(19) United States
(12) Patent Application Publication
(10) Pub. No.: US 2016/0042914 A1
(43) Pub. Date: Feb. 11, 2016

(54) ACHROMATIC DUAL-FIB INSTRUMENT FOR MICROFABRICATION AND MICROANALYSIS

(71) Applicant: Frederick Wight Martin, North Stratford, NH (US)

(72) Inventor: Frederick Wight Martin, North Stratford, NH (US)

(21) Appl. No.: 14/816,185

(22) Filed: Aug. 3, 2015

Related U.S. Application Data
(60) Provisional application No. 61/999,811, filed on Aug. 7, 2014.

(51) Int. Cl. H01J 37/22; H01J 37/28

(52) U.S. Cl. CPC H01J 37/22; H01J 37/28; H01J 2237/31749; H01J 2237/2813

(57) ABSTRACT

A mulch-beam focused ion beam instrument containing a micro fabrication beam (1) for sputtering and surface polishing and a micro analysis beam (2) which passes through a spherically and chromatically corrected quadrupole objective lens system (5), for use with bulk specimens (8) and detectors (6, 7) or transmission specimens (9) and transmitted particle detectors (10, 11).

### FIELD

The invention relates to processing of integrated circuit wafers, both microanalysis and microfabrication; and to use of focused ion beams for other purposes in fields such as biotechnology, materials science, and catalysis

### BACKGROUND

The resolution of the scanning electron microscope as it examines a specimen is limited by backscattering of electrons in the specimen. Electrons incident at a fixed spot suffer multiple scattering from atoms in the specimen, reverse direction, and emerge in a region of finite size centered on the point of incidence, causing further emission of type SE2 secondary electrons as they emerge. For example, 20 KeV backscattered electrons emerge from a region with a radius as large as 1 micron [Reimer, Image forming in low-V scanning electron microscopy (SPIE, Bellingham Wash. 1992), page 2].

In integrated circuit processing plants, SEMs are combined with focused ion beams. In these dual-beam instruments the focused ion beam is used to sputter away material in a region of interest, so that defects below the surface may be examined with the SEM prior to repair. However as microcircuitry becomes smaller than the resolution limit set by backscattering, the electron beam is no longer useful. Instead a complicated process of sputtering around the region of interest and rotation/translation of the specimen is used [Williams, Microscopy Today 22 (4) (2014) 32-36], such that a small piece of the specimen is cut out. It is then placed on an electron microscope grid, further thinned with an ion beam, and finally examined in a separate transmission electron microscope (TEM). The patent literature contains many examples of variations on this theme. Not only are such steps time consuming, but they inevitably introduce surface contamination. It is an object of the invention to eliminate all the steps necessary to produce the TEM specimen, including the complex rotation/translation stages necessary to enable cutout with a FIB, removal of the specimen from the IC wafer, thinning while mounted on the TEM grid, and separate TEM analysis.

Ion beams have much less backscattering of the primary beam, because of the factor 2000 in mass of the lightest ion beam relative to the electron. In a focused-ion-beam (FIB) instrument, most secondary electrons are of the SE1 type arising from the area where the primary beam enters the specimen. For the present helium microscopes, the beam diameter limit is about 0.3 nm [Scipioni et al, Microscopy Today 15 (2007)12]. However the diameter of the region of emergence of SE2 electrons can be as large as 100 nm for light ions in materials of high atomic number [Scipioni et al, J Vac Sci Tech B27 (2009) 3254: FIG. 10], and although they are much less intense than the SE1 electrons, they form a halo or fog in scanned images. If soft X-rays rather than secondary electrons are used, only atoms which are in the path of the ion beam are detected. Because the ion beam travels nearly unscattered within the attenuation length of soft X-rays inside the specimen, resolution is then determined by the focusing ability of the lenses used to form the focused ion beam. It is an object of the invention to enable scanning microscopy at resolutions smaller than the limit set by the SE2 electrons [Martin, Microsc. Microanal. 20 (3014) 1619].

Although the prior art includes mention of dual-beam instruments where both beams are ions [Ito, U.S. Pat. No. 8,274,063 (2012)], it does not include ion optical systems comprising achromatic objective lenses. An “ion optical system 25” is included in the specification and drawings of the prior art, but is not further defined or included in the “ion beam irradiation system” of the claims. Although its nature is not specified, the system 25 shown in the drawing apparently comprises the typical cylindrical electrostatic lens well known in the art. Such lenses suffer from chromatic aberration. In order to maintain small aberrations in electrostatic systems, a short working distance must be used, leading to designs with conical protruding lens holders designed to avoid interference with each other. It is an object of the invention to compensate chromatic aberration by using interleaved quadrupole lenses of achromatic design, thereby leading to both smaller spot sizes and longer working distances.

In addition, energies of 30 KeV must generally be used in order to reduce the percentage effect of the inherent energy spread of typical gallium liquid-metal needle-type sources, leading to excessive penetration depth and displacement damage energy spread. Current into a focus of fixed size also falls as the cube of the ion energy, causing increase in processing time by a factor of 1000 if 3 ken ions are used. It is an object of the invention to produce 3 KeV beams which can be used for surface treatment in useable processing times.

The prior art [Ito, U.S. Pat. No. 8,274,063 (2012)] also includes specification of the process of micro-machining of a flake with the dual ion beams followed by scanning ion microscopy of a helium ion beam transmitted by the flake. The prior methods and claims include the “ion beam irradiation system” combined with a transmitted ion detector and an image displaying device. Neither the method nor the claim include use of achromatic objective lenses. In addition the method does not specify adjustment of lens aberrations.

### BRIEF SUMMARY OF THE INVENTION

A multi-beam instrument with at least two FIBS can overcome the resolution limit of the SEM, and the need to extract and transfer specimens for examination in an electron microscope. One FIB has an ion source optimized to produce the high currents for sputtering silicon, and the second has an ion source optimized to produce resolution smaller than an SEM, and an objective lens optimized for achromatic operation at large working distance. Use of such lenses enables scanning ion microscopy at improved resolutions and low energies which cannot be obtained with electrostatic lenses.

This instrument can be used for in-situ microanalysis on an IC wafer of large diameter. The wafer is indexed to the point of intersection of the two beams, the sputtering beam is used to mill away a layer of material in a small region of interest, and the high-resolution beam is used to read out or to alter what is found at the surface of the newly eroded material.

The instrument is also useful for microfabrication, such as surface modification for circuit repair by irradiation or implantation, using ions selected from many different atomic numbers at energies lower than available from typical systems based on electrostatic objective lenses

### DESCRIPTION OF DRAWINGS

FIG. 1 shows a microfabrication beam (as part of a system)

FIG. 2 shows a microanalysis beam and detectors (as part of a system).

FIG. 3 shows scanning transmission ion microscope operation of a microanalysis beam (as part of a system).

### LIST OF REFERENCE NUMBERS

1. Microfabrication beam

2. Microanalysis beam

3. Microfabrication ion source

4. Microanalysis ion source

5. Cc,Cs corrected objective lens

6. Secondary electron detector

7. X-ray detector

8. Bulk specimen

9. Transmission specimen

10. Particle detector

11. Annular particle detector

### DETAILED DESCRIPTION

The multi-beam FIB instrument has ion beams from at least two sources, each one optimized for a different purpose. The microfabrication beam 1 has a high current of ions for sputtering, at a resolution sufficiently small to enable milling the feature of interest. The microanalysis beam 2 produces an ion beam with a small resolution, at as high a current as is feasible in order to minimize inspection time. Typically the sputtering source 3 can be a gallium liquid metal ion source (LMIS) or a xenon plasma source [Smith, U.S. Pat. No. 8,405,854]. By changing the gases in a plasma source, ions suitable for heavy micromachining and light polishing may be obtained. The microanalysis source 4 can be a gas field ionization source (GFIS) consisting typically of a tungsten needle at high voltage surrounded by the gas of interest. For highest resolution it can be an atom-emitter source, which is a GFIS with a single crystal needle treated to form atomic-scale pyramids on its surface, from only one of which the ion beam is drawn. Typically the atom-emitter source produces singly charged helium ions. To analyze emanations produced when the FIB intersects a specimen, various detectors are provided. These comprise a secondary electron detector 6 and an x-ray detector 7. Also detectors for ions, a micromanipulator, a gas jet for providing molecules that may be polymerized or activated by the ion beam, or an SEM column for observing during microfabriation may be provided.

The analytical beam 2 is focused by a Cs (spherical aberration) and Cc (chromatic aberration) corrected objective lens 5, consisting of a pair of achromatic quadrupole lenses and an associated multipole lens. The quadrupoles are made of interleaved electric and magnetic quadrupoles, forming an 8-pole structure which in each lens which can be excited as an octopole for Cs correction. The details of the objective lens are described in prior publications (Martin US 2013/0264477 A1; Microscop. Microanal 20 (2014) 1619; Microscopy & Microanalysis conference 2013, posters 110, 360 (different from abstract, downloaded at www.nbeam.com Jul. 29, 2015); U.S. Pat. No. 5,369,279) which are incorporated here by reference.

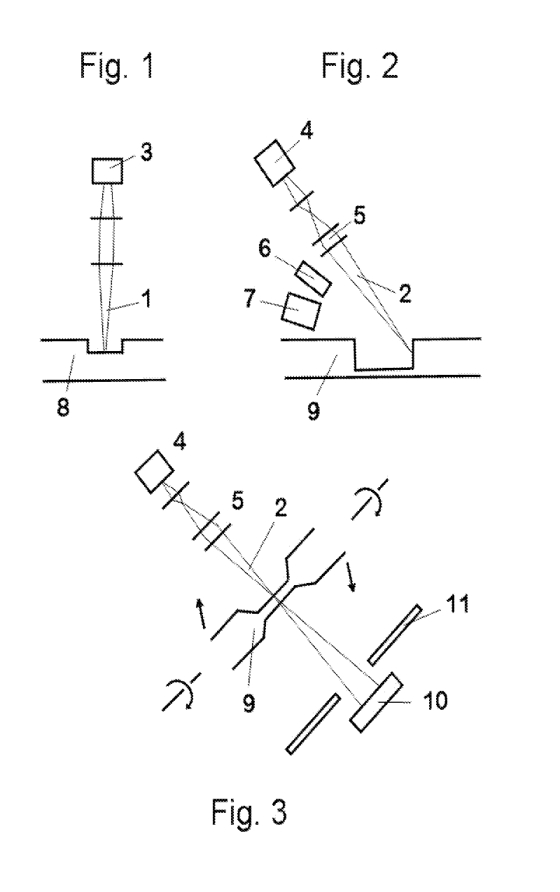

FIGS. 1 and 2 show each of the dual FIB columns separately, omitting the other column for simplicity. FIG. 1 shows the microfabrication beam sputtering a small region of interest in the specimen 8 which can be an integrated circuit mounted in an x-y stage. FIG. 2 shows a subsequent use of the analytical beam 2 to examine layers at different depths from the sample surface, immediately after sputtering without motion of the specimen. The beam 2 can also be swept along the bottom of the region of interest, producing a plan of integrated circuitry at the current sputtered depth.

In FIG. 2 the specimen can then be rotated as shown in FIG. 3 if desired so that beam 2 becomes perpendicular to the specimen surface. FIG. 3 also illustrates means for rotation to expose both sides of the specimen, which can be done for sputtering and polishing without moving the specimen on its stage or taking it out of vacuum. FIG. 3 shows transmission microscopy of a specimen rotated in this way (or alternatively mounted in a specimen holder at the appropriate fixed angle to the plane of an x-y stage). Particles transmitted by specimen 9 are registered by detector 10. This detector can be for example an active pixel sensor capable of registering the x-y position of arrival of each particle, or a scintillator-TV camera combination. Transmitted particles may also be detected by annular detector 11, which registers particles scattered to angles outside its central aperture.

The advantage of transmission microscopy is that each single ion in the analytical beam 2 is counted, and that the high energy of the beam makes detection easier over noise. When radiations such as secondary ions, electron, or X rays are used, there are some primary ions which produce no such radiations, and when they are produced, the detector cannot cover the whole hemisphere over which they emerge.

In its best mode, the invention may comprise an ion source of the magneto-optical trap variety. Because their emitting vapor is cooled to millikelvin temperatures, thereby reducing momentum components transverse to the axis of the ion beam column, such sources can be made with brightness of 10⁷ A per m²-sr-eV, ten times brighter than Ga-coated needle-type sources [Knuffman, Steele & McClelland, JAP 114 (2013) 044303]. In this mode, the inherent energy spread of the laser-excited ion source does not matter because the objective lens is achromatic. In addition, the Cc/Cs compensated lens of the invention can be adjusted to compensate the spherical aberration of the extraction lenses and accelerating column. The proper amount of compensation may be determined by methods such as observing the perfection of the focused beam at the specimen plane [Uhlemann & Haider, Ultramicroscopy 72 (1998) 109; Krivanek US patent 20040004192] or experimental ray tracing after ions have passed through an apertured specimen [Martin US 2013/0264477 A1, incorporated above by reference]. Because the objective is achromatic, the focusing may be done at energies as low as 4 KeV, as often desired to reduce atomic displacement effects in the bulk of a specimen, whereas systems based on electrostatic lenses typically require energies of 30 KeV to minimize effects of chromatic aberration. The combination of magneto-optical source and Cc/Cs corrected objective lens thus enables a finely focused ion beam to write at energies 10 times lower and speeds 10 times greater than typical Ga ion beams.

Magneto-optical sources enable beams from a wide variety of atoms to be made [Steele et al, JVST B28 (2010) C6F1, FIG. 1], and may be operated in pulse mode such that single ions may be delivered [Hill & McClelland, Appl Phys. Letts 82 (2003) 3128]. When the FIB is rastered by a deflection system, these characteristics enable implantation of a single ion through an achromatic objective lens into a desired (x,y) position in a substrate.

While the above description is specific, it should not be construed as limiting the scope of the invention, but rather as an examples of preferred embodiments. Other variations are possible. Accordingly the scope of the invention should be determined by the appended claims.

1. An improved dual-beam FIB instrument comprising one or more FIB columns, in which the improvement comprises a Cs and Cc corrected quadrupole objective lens in at least one FIB column.

2. The method of utilizing the instrument of claim 1 comprising the steps of:
1) providing a specimen such as an integrated circuit on an x-y locating stage
2) indexing a feature of interest to the location of the microfabrication beam
3) sweeping the microfabrication beam to sputter away material to create a region for microanalysis
4) placing the microscope beam onto the newly micromachined region, and
5) sweeping the microscope beam and utilizing associated electronics to create images of the specimen.

3. The method of claim 2 further comprising utilization of the associated electronics to detect any of the following emanations produced by either ion beam:
1) secondary electrons
2) x-rays
3) secondary ions
4) ions from a FIB which have been scattered by the specimen
5) ions from a FIB which have been transmitted by the specimen.

4. An improved Cs and Cc corrected FIB instrument as in claim 1, in which the improvement further comprises detectors of primary ions which have been transmitted by the specimen.

5. The methods of utilizing the instrument of claim 4 to produce images by detecting any of the following:
1) the energy loss of transmitted ions (STIM)
2) The scattering of primary ions into an annular detector
3) the x-y position of arrival of scattered primary ions.

6. The method of utilizing the instrument of claim 4 comprising the steps of
1) utilizing the micromachining beam to etch and polish a region for microanalysis
2) turning the specimen over, for instance by rotating a half turn about an axis perpendicular to the direction of the ion beam
3) utilizing the micromachining beam to etch and polish the back side of the specimen, thinning it to a desired thickness, and
4) using the detectors of transmitted primary ions and associated electronics to form an image.

7. The method of utilizing the instrument of claim 4 comprising the steps of
1) utilizing an apertured specimen
2) using a detector of primary ions and associated electronics capable of producing an image, and
3) adjusting excitations of the Cc/Cs corrected objective lens to produce minimum aberration in the image.
